(19) United States
(12) Patent Application Publication
(10) Pub. No.: US 2002/0161536 A1
(43) Pub. Date: Oct. 31, 2002

(54) Internet ready, energy meter business methods

(76) Inventors: Sung L. Suh, Palo Alto, CA (US); Lucian X. Dang, San Francisco, CA (US); Virgil G. Rose, San Mateo, CA (US)

Correspondence Address: RICHARD ESTY PETERSON, PATENT ATTORNEY, 1905-D PALMETTO AVENUE, PACIFICA, CA, 94044, US

(21) Appl. No.: 09/834,346

(22) Filed: Apr. 13, 2001

Related U.S. Application Data
(63) Continuation-in-part of application No. 09/558,391, filed on Apr. 25, 2000.

(51) Int. Cl. G06F 19/00; G01R 21/00; G01R 21/06

(52) U.S. Cl. 702/62

(57) ABSTRACT

An internet ready electronic power meter with automatic reporting capabilities, the electronic power meter recording electrical power usage and other utility usage, and periodically transmitting utility usage reports to a remote site using internet and conventional protocols of the public or private computer network, with selective access of customer data by customers and others for determining usage and accounting matters, with added capabilities of site automation, site security and appliance controls providing new business models for revenue generation.

This application is a continuation-in-part of our application Ser. No. 09/558,391, filed Apr. 25, 2000, entitled, Internet Ready Electronic Power Meter With Automatic Reporting.

### BACKGROUND OF THE INVENTION

This invention relates to a power supply meter and in particular to an internet ready electronic power meter for residential or commercial use that records the rate of electronic power usage and communicates the usage rate to a remote site permitting new business models for revenue generation. In its preferred embodiment, the electronic power meter of this invention utilizes the public or private computer network to enable the electronic power meter to communicate recorded data to a service provider with access by clients and customers for review of the recorded data.

The modern energy environment, with competition in providing electric power to commercial and residential customers requires a competitive price and superior service. Service and pricing advantages may result in selection of one provider over another. In industrial countries, the cost of electrical power may vary according to the amount of usage, the time of day, or day of the week of usage. Off-peak hours may cost a client or customer less than usage during peak hours. Similarly, use of electrical power during a weekend may cost a large electrical power user substantially less than during the week. Additionally, the ability to track power usage in real time is advantageous to both the service provider and the customer or client and enables site automation, site security and appliance controls.

In non-industrial countries or in environments where reading an on-site meter is impractical or not cost effective, the use of a remote data collection system can add efficiencies to a power service company in reading meters and billing customers.

Although electronic power meters have been developed to accurately determine power usage, such meters have not taken advantage of digital data collection and distribution. Typically, electronic power meters are read visually or with data collection probes that are directly connected to the meter.

The inventors of the subject electronic power meter have utilized the efficient digital data collection format of electronic meters and have greatly enhanced the utility of digital reporting techniques by transmitting the collected data to a remote site over the public network using standard communication protocols. This enhanced capability enables the service provider to offer clients and customers custom usage plans with enhanced report generation capabilities, including customer access to current usage and cost profiles enabling the client or customer to adjust usage and maximize cost savings.

These and other advantages are described in the summary of the invention that follows.

### SUMMARY OF THE INVENTION

The internet ready electronic power meter of this invention incorporates a communication component that enables the electronic meter to communicate in a dedicated local area network (LAN) or wide area network (WAN) including a public or private network, such as the internet also called the world wide international computer network. The invented electronic power meter includes the communication components necessary to communicate by telephone line, power line or wireless communication systems to periodically transfer collected data to a remote site.

In a preferred embodiment, the remote site is the information service provider in control of the electronic power meters, where customer and client billings relating to meter data are prepared. It is to be understood that the service provider may be the power provider or power broker, or, simply a billing service. The service provider is able to provide access to its customers and clients, through the world wide web, to review current energy costs, or, depending on the richness of the data provided, review a full profile of power usage and energy costs over a period of time.

In the preferred embodiment, the electronic meter of this invention includes a digital display for visually reading the meter and a probe socket for the terminals of a portable optical meter reader, which are typical features of a state-of-the-art electronic power meter.

In the invented internet ready electronic meter an automated meter reading module is coupled with a communications module to read, record and transmit data to a remote site. The preferred embodiment of the communications module comprises a telephone modem that connects to a switched telephone network for transmitting collected data to the service provider at a remote site. The remote site is typically the service and accounting center of the company providing or brokering the electrical power. In this manner the service and accounting center or service provider can monitor power usage according to time and date of usage, and generate user profiles and user billings for power usage and respond to any events detected in the power network.

The frequent remote collection of usage data allows for availability of up-to-date information on power usage. Using current web site development techniques, the collected data is preferably made available to usage customers and clients, who may be the actual power consumers or have other relationships with the service provider. In this manner, using restricted access techniques, a customer, after proper authentication, can access its usage database and obtain current information about its usage and charges. Depending on the richness of the data provided the information may be simply current cumulative usage and charges, or time and date usage profiles, including rate variation for off-peak hours, and other information useful in planning operations to minimize electrical power costs.

It is to be understood that the communication module may include a radio frequency transceiver for wireless communication of collected data to a wireless service provider for routing to the data collection center, here the service provider.

These and other features of the electronic power meter with automated meter reading and reporting are described in greater detail in the detailed description of the preferred embodiment that follows.

### BRIEF DESCRIPTION OF THE DRAWINGS

FIG. 1 is a perspective view of the electronic power meter in a typical cylindrical housing.

FIG. 2 is a schematic block diagram of the electronic power meter showing data collection and communication circuits.

FIG. 3 is a schematic block diagram of the battery charging circuit for the electronic power meter.

FIG. 4 is a schematic block diagram of the communication protocol of the electronic power meter for communicating data to a remote site.

Fig. 5 is a flow chart for data collection and communication for the electronic power meter.

FIG. 6 is a schematic illustration of a utility management system using the electronic meter of this invention.

FIG. 7 is a schematic illustration of the utility management system of FIG. 6 with added features.

### DETAILED DESCRIPTION OF THE PREFERRED EMBODIMENTS

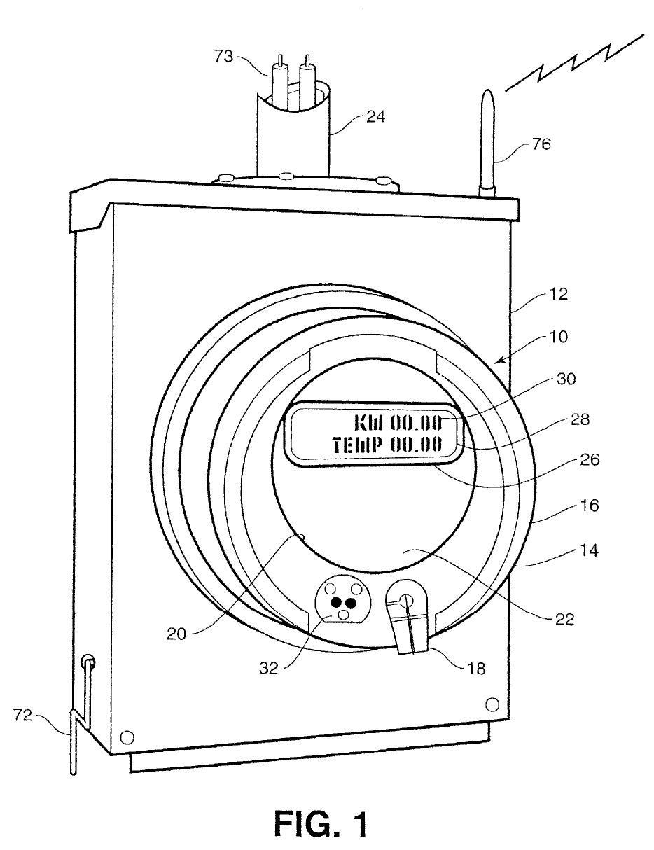

Referring to FIG. 1, the electronic power meter with automatic reporting, designated generally by the reference numeral 10, is shown mounted on a power service panel 12. The electronic power meter 10 includes a cylindrical housing 14 with a coverplate 16 having a locking latch device 18 to prevent unauthorized use of demand and test functions. It is to be understood that the electronic power meter can be housed in a housing having a square, rectangular or other configuration.

The coverplate 16 has a transparent viewing face 20 fabricated of glass or plastic permitting visual inspection of an internal faceplate 22 on which are recorded the specifications of the particular meter. As noted, the electronic power meter may be designed for commercial or residential use and configured for a particular power supply 24.

The faceplate 22 has a window 26 with a liquid crystal display 28 (LCD) that displays markings 30 that represent the cumulative power usage, typically in kilowatt-hours. It is to be understood that the markings may indicate the temperature, the rate of power usage as well as other information considered important by the customer or party that visually views the meter.

The internal electronics periodically captures a reading of power usage and accumulates a record of usage over a period of time. This record can be retrieved by an optical meter reader (not shown) having optical probes that are inserted onto the optical terminal socket 32. In this manner usage records can be retrieved by a meter reader in a conventional manner.

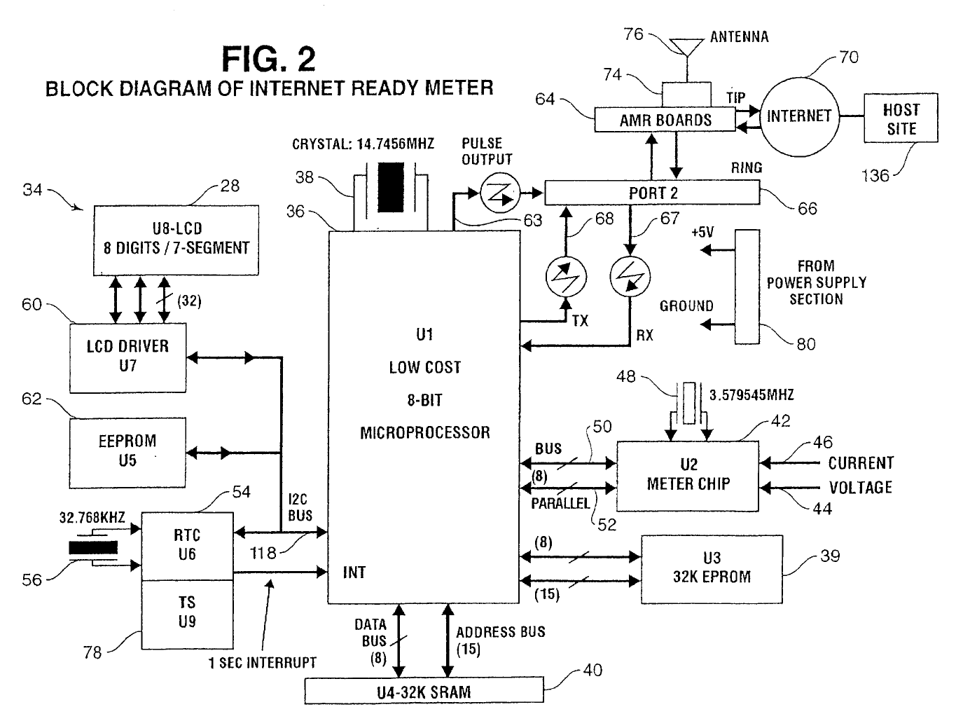

Within the housing 16 of the electronic power meter 10 is an electronic main circuit designated generally by the reference numeral 34 and shown in FIG. 2. Referring to FIG. 2, the electronic power meter 10 has a microprocessor 36 to handle the operations and tasks of the meter. The microprocessor 36 is a low-cost, 8-bit processor having an associated crystal clock 38, a fixed memory 39 for programmed control instructions and a random memory 40 for data storage. The fixed memory, also identified as U3, includes the program memory that contains the assembly code and the internet protocols such as TCP/IP, SMTP and PPP as described hereinafter. The random memory 40, also identified as U4, contains the data of the meter readings and other information used in creating data records or specialty features of the electronic power meter 10. The microprocessor 36 coordinates periodic readings of the meter chip 42 connected to the power supply 24 to generate digital representations of the voltage 44 and current 46, as schematically illustrated. The meter chip 42, also identified as U2, is a module with its own crystal clock 48 and data lines 50 and 52 feeding data to the microprocessor 36. The meter chip 42 is a commercially available AC meter chip. The interface with the microprocessor 36 may be parallel, as represented by line 50, serial as represented by line 52, or by busses such as SPI and 12C.

Additionally, to coordinate usage with the time of day of such usage, a real time clock chip 54, also identified as U6, is provided. The real time clock chip 54 includes a clock crystal 56 and preferably circuitry or programming to determine date as well as time. This data is transferred to the microprocessor 36 when polled during periodic reading of the power meter chip 42.

The preferred embodiment of the electronic power meter 10 includes a temperature chip 78, also identified as U9, that generates a digital representation of the temperature which is transferred to the microprocessor 36 concurrently with real time clock data. In this manner, a record of temperature is generated with the record of power usage on periodic sampling. This periodic temperature reading can be accessed by the client or customer and, if desired, used by the client or customer for temperature control functions, for example, regulation of air conditioning systems.

The liquid crystal display 28, also identified as U8, has an associated display driver 60, also identified as U7, and a memory 62, also identified as U5, for displaying current readings as updated by processed data from the microprocessor 36. The non-volatile memory 62 also contains permanent data and coding that must be kept if power is lost. A pulse output 63 from the microprocessor 36 is transmitted to the ports 66 for the optical terminal socket 32 of FIG. 1.

The microprocessor 36 is operably connected to a modem 64 which is preferably, but not required to be, mounted within the housing 16. In the circuit 34 of FIG. 2, the modem 64 is contained within the housing 16 and connected via ports 66 to the microprocessor input 67 and output 68. The modem 64 is either line connected to the international computer network 70 via communication lines 72, power line 73 using developed data transmission overlay technologies or, using a transceiver 74 via airway transmissions through an antenna 76, as also shown in FIG. 1. The electronic power meter is able to connect directly to any ISP of any web site.

In a preferred embodiment, the configuration described has a temperature sensor chip (TS) 78 that digitally represents the current temperature which is sampled and recorded by the microprocessor 36 concurrently with the acquisition of the time, and preferably the time and date, when reading the current power usage data generated by the meter chip 42. For convenience, the real time clock chip 54 and temperature sensor chip 78 are mounted on the same circuit board as the meter chip 42.

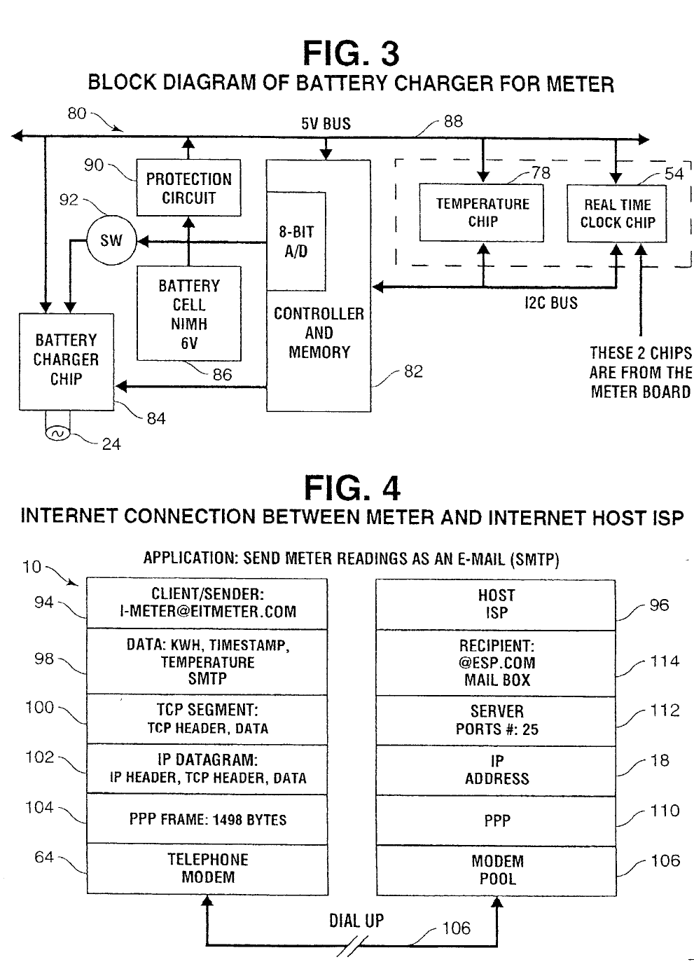

Referring to FIG. 3, a subcircuit 80 is schematically illustrated as a block diagram. The five volt D.C. power supply for the main circuit 34 includes a controller and memory unit 82 to control a battery charger chip 84. The battery charger chip 84 is connected to the A.C. power supply 24 with a low energy tap for conversion to low voltage D.C. power to maintain a full charge on a six volt, nickel/metalhydride battery cell 86. The six volt battery cell 86 is connected to the five volt power bus 88 comprising the power supply for the main circuit 34 through a protection circuit 90. The protection circuit 90 maintains the service voltage to prevent damage to the low voltage components of the main circuit 34 from surges, spikes and other irregularities. The controller and memory unit 82 controls the battery charger chip 84 and charge supply switch 92 and regulates the charging of the battery cell 86. In the event of a power outage in the power supply 24, the outage is sensed and the battery cell 86 powers the electronic main circuit 34 of the electronic power meter 10. In this manner the operation of the main electronic circuit 34 is not affected and the power outage event is recorded during sampling and reporting. This remote sensing at the service center triggers a response to the power outage which may comprise a simple alert or initiation of a positive response.

As shown for emphasis in FIG. 3, the temperature sensor chip 78 and real time clock chip 54 are powered by the five volt bus 88 with the battery backup to provide data even during a power outage.

Shown in FIG. 4 is the preferred communication protocol between an electronic power meter 10, designated in FIG. 4 as the client/sender 94, and the service provider, designated in FIG. 4 as the host 96. It is to be understood that the service provider 96 is here the remote recipient of the data, and is typically the data collection center for accounting. The service provider as noted may have other roles from tracking and servicing the meters to a fully integrated operation including providing or brokering the electrical power to the ultimate residential, commercial or governmental user.

In the system shown in FIG. 4, the electronic power meter 10 is the chent/sender 94 of the data records including the kilowatt hour usage rate, the time stamp, and the temperature. The data records are sent as an e-mail 98 using standard international computer network protocols. The e-mail conforms to SMTP (Simple Mail Transfer Protocol). The second transmission protocol layer 100 adds the TCP (Transmission Control Protocol) header including formatted data identifying the e-mailer and host, here the electronic power meter 10 acting as the client/sender and the service provider as host 96.

In the subsequent layer, the IP (Internet Protocol) is added to comprise the IP datagram 102 including the IP header, the TCP header and the data. Finally, the PPP (Point to Point Protocol) format 104 packages the message in the 1498 byte frame for transmission by the telephone modem 64.

On the host side of the communication path, the host ISP (Internet Service Provider) utilizes a modem pool 106 to assure timely throughput for client/sender datagrams to its IP address 108 using the PPP format 110. Customarily, the host server has multiple ports and advantageously has a dedicated server port 112 for the periodic electronic datagrams sent by the number of active electronic power meters in place.

Since each client/sender has a telephone number identifying the modem, two-way messages can be sent via the dial-up line 106. This allows the client/sender, when properly programmed, to receive messages, such as a prompt to activate or send a cumulative log or other pre-programmed tasks. The client/sender modem should include a minimum 16K/ROM program memory, and 8K-SRAM for storage of 8 packets, each packet length being 1000 bytes. The processing time is dictated by the telephone modem speed, typically 2400 bps to 33,600 bps, which are cost efficient for the data transfer.

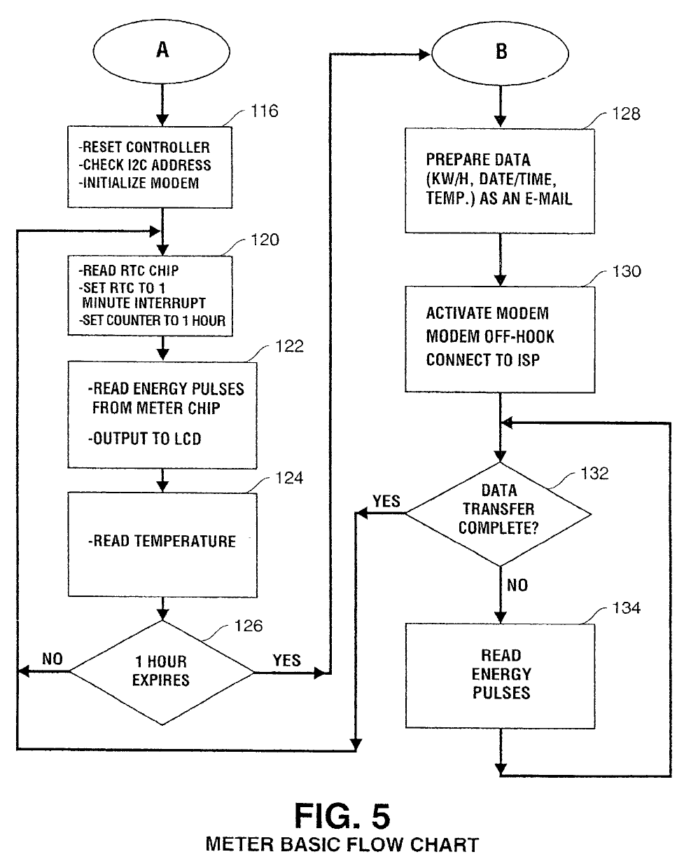

The basic process for collecting, storing and transmitting data by the electronic power meter 10 is shown in the flow chart of FIG. 5. In column A the internal reading and data collection routine is outlined. In column B the data transmission and storage routine is outlined. Starting at the top of column A, in the first block 116, the microprocessor 36 is reset, the I2C address on the 12C bus 118 in FIG. 1 is checked and the modem 64 initialized.

In the second block 120 the real time clock chip 54 is read and set to the programmed interrupt period for accessing data. Here a one minute interrupt is programmed with the counter set to one hour. Data polling occurs each minute and processed for transmission each hour. These time periods can be changed according to the preferences of the service provider.

In block 122 the output of the meter chip 42 is read with a representation of current energy consumption also being sent to the LCD. In block 124 the output of the temperature sensor chip 78 is read.

At decision diamond 126 the counter is checked to determine if one hour has expired. If no, the data collection routine is repeated the following minute. If yes, the collected data is prepared for messaging to the data collection center, that is the host ISP 96.

In column B, where the data transmission and storage routine is depicted, the data collected is prepared as an e-mail package in block 128.

In block 130, the modem is activated and an off-hook connect to the ISP is effected. At decision diamond 132 it is determined if the data transfer was successfully completed. If no, a read of energy pulses is continued in block 134 and the process loops back to decision diamond 132. If yes, the data is saved and the data collection routine is repeated for the next transmission. The saved data is stored in the random memory and available for access by an optical meter reader or by remote access initiated by the host.

It is to be understood that the system disclosed may be modified without departing from the spirit of the invention as disclosed in the written description of the preferred embodiment. As noted, in areas where use of telephone lines are impractical or unavailable, the data transmission may be performed by wireless communication systems. Other modifications may be made to adapt the system to the particular needs of a service provider or customer. For example, the host ISP 96 in FIG. 4 may have a host web site 136 as shown in FIG. 2. The host web site 136 has a customer or client access using a browser and access authorization code. The web site posts the saved data with restricted access limited to the particular client or customer whose information is to be viewed. Additionally, the data collected by the host can be analyzed and manipulated for graphic presentations to enhance the appeal to the customer viewer.

The internet ready electronic power meter described with reference to FIGS. 1-5 enables these new business models to extend to one or multiple service providers in the utility market. In the described embodiment, the electronic meter provides a real time record of power usage and communicates this record to a service provider periodically as programmed or responsively when polled. The internet ready meter is designed to communicate real time records of other data samplings, for example, site temperature, to the service provider. It is to be understood that additional utility measurements, such as gas and water usage can piggyback on the primary data on energy during communication sessions. An electronic water or gas meter connected to the internet ready power meter comprises a hardware client that acts like a controller appliance. An on-site electronic water meter, gas meter or other commodity meter, that measures rate of use in addition to cumulative use, can generate a rate of use signal that can be monitored, and if necessary interpreted, by the internet ready electronic power meter of this invention. The internet ready electronic power meter will generate and store a rate of use record for that utility. The rate of use record provides a profile of real time usage which can be combined with the cumulative use record for highly flexible pricing schemes for each utility. The internet ready electronic utility meter functions as the communicator hub for satellite appliances or systems that periodically communicate with the internet ready power meter of this invention. The report may be by analog or digital electronic signals which are processed and stored as digital records by the electronic utility meter for periodic transfer to the system or service provider.

The service provider may be the system provider that provides the hardware systems that include the internet ready electronic utility meter, the provider of one or more of the utilities or commodities being metered, or an intermediary such as a broker, billing service, or information marketeer.

With the client base expanded, and the customer options multiplied, the business models for generating revenue become highly flexible. The real time electronic power meter functions as a general internet ready electronic utility meter providing real time site monitoring or automation. For convenience, the real time internet ready power meter is characterized as an energy meter.

Referring to FIG. 6, the energy meter 10 is provided in an intra/inter-net communication system 148 that allows for flexibility in the design of business models for generating revenue through use of the invented meter. The internet connected energy meter 10 in the system of FIG. 6 functions as a hub for data transfer to and from clients of the energy meter 10 including the site water service 150, the site gas service 152 and site operations automation 154. Using the internet communication system 156 the internet ready power meter communicates with the primary service provider 159, here the energy service provider (ESP), an entity with primary control over operation of the energy meter network. The energy service provider 158 in turn communicates through the internet communication system to clients of the energy meter service provider 158 which may be separate or independent entities, and are, for example, utility providers 160, customer information providers 162, automatic meter reading vendors 164 and/or billing services 166. One or more of these entities are considered energy meter service provider clients.

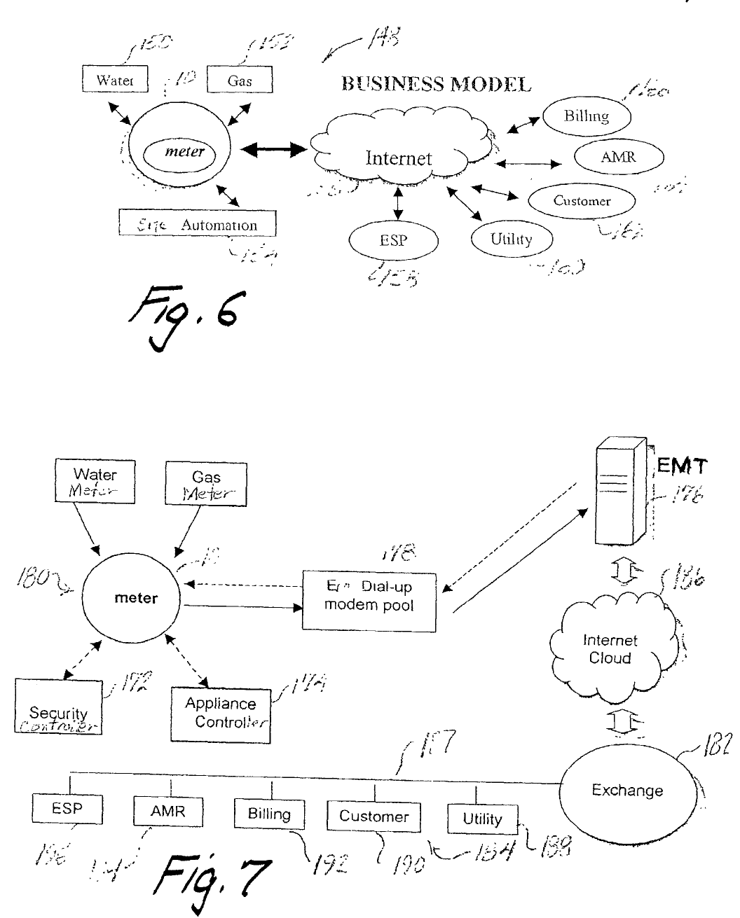

Referring to FIG. 7, the basic system of FIG. 6 is expanded and further defined. As noted in reference to FIG. 2, the energy meter 10, being equipped with automatic meter reading boards 64 which can receive and interpret signals from other meter devices, for example, an electronic water meter 168 for the water service 150 of FIG. 6, or an electronic gas meter 170 for the gas service 152 of FIG. 6. Other input and output signals are transmitted through port 66 to operate and monitor other electronic system controllers such as a site security controller 172 or appliance controller 174. This permits control of or response to site security situations or control and operation of site appliances like air conditioners, heaters, lights and other appliance systems that are clients of the power meter 10.

In the customary system, multiple meters of the type shown in FIG. 7 communicate with a remote host 176 typically through a dial up modem pool 178 through one or more of the multiple communication pathways 72, 73 or 76 shown with reference to FIG. 1.

The remote host 176 of FIG. 7 is the system intermediary such as the system provider of the energy meter technology (EMT) which installs and maintains the hardware systems and transmits the communications back and forth between the local site energy meter hubs 180 and the host 176. The host 176 may be the same entity or a separate entity from the information exchange 182 which converts the raw data from the energy meter hubs 180 into usable information for one or more clients 184 of the exchange 182.

Preferably, the information exchange 182 and the manager of the energy meter technology 176 communicate through the internet cloud 186 for convenience and minimization of resources and expense for what are essentially data exchanges. The information exchange 182 communicates with its clients 184 by a multimedium communication pathway 187, which includes web site broadcasts and restricted access internet pathways including e-mail, restricted web site page displays, telephone, mail and any other conventional or custom medium.

For purposes of illustration, a typical pathway includes a particular utility 188, the customers of the utility 190, a billing service 192 for the utility and its customers, automatic meter reading services or vendors 194 of the energy meters for the utility, and an energy related service provider 196 which can range from the supplier of the energy related medium, such as gas, water, electricity, commodities, back to the host 176 operating the energy meter hubs.

While, in the foregoing, embodiments of the present invention have been set forth in considerable detail for the purposes of making a complete disclosure of the invention, it may be apparent to those of skill in the art that numerous changes may be made in such detail without departing from the spirit and principles of the invention.

1. A utility management system for a network of sites being provided with an electric utility service comprising:
providing at each site, an energy meter having a connected modem with the energy meter metering energy usage and periodically recording the rate and time of energy usage as periodic usage records;
storing the periodic usage records in a memory associated with the energy meter;
providing a computer network communication system with a host remote from the sites provided with an energy meter, the communication system connecting the provided energy meters to the host using the connected modems for communications between the individual energy meters and the host wherein data representing stored periodic usage records is periodically communicated from the energy meter to the host;
processing the data representing stored periodic usage records as energy information;
marketing the energy information to clients of the host.

2. The utility management system of claim 1 wherein the energy meter has means to store records of utility usage in addition to the usage of energy from an electric utility service.

3. The utility management system of claim 2 wherein the energy meter connects to controllers of systems at the site provided with the energy meter with the management system further comprises controlling the systems at the site via the computer network communication system.

4. The utility management system of claim 3 wherein clients of the host utilize information provided by the host to regulate systems at the site by remote communications to the energy meter.

5. A method of managing utility usage at a plurality of sites, each site provided with an electronic utility meter having a modem for communicating usage, comprising the steps of:
metering the utility usage and periodically recording the time of usage and the rate of usage with the electronic utility meter;
storing each recorded time of usage and rate of usage of the utility as a memory record in the utility meter;
establishing a primary service provider remote from the sites provided with the electronic utility meter, the primary service provider having a computer communication system that connects with the electronic utility meter;
periodically communicating the stored memory records of the electronic utility meter to the primary service provider via the communication system that connects the service provider with the electronic utility meter.

6. The method of claim 5 wherein the electronic utility meter generates records of cumulative usage of the utility and communicates the records of cumulative usage to the primary service provider.

7. The method of claim 5 wherein the service provider generates information about utility usage at each site wherein each site has a utility meter user and the service provider provides information about utility usage at a select site to the utility meter user at that select site.

8. The method of claim 5 wherein the service provider has an information exchange with clients of the information exchange that are interested in information about utility usage at the sites having electronic utility meters wherein the service provider provides selected information about utility usage at sites having electronic utility meters.

9. The method of claim 5 wherein the electronic utility meter has means for metering multiple different utilities provided to the site and periodically communicating records of usage of each utility to the primary service provider.

10. The method of claim 5 wherein the utility meter has means for remotely controlling appliances at the site of the electronic utility meter in response to costs for the utility being provided.
